(19) United States
(12) Patent Application Publication
(10) Pub. No.: US 2013/0208406 A1
(43) Pub. Date: Aug. 15, 2013

(54) ELECTRONIC DEVICE AND BIAXIAL PIVOT THEREOF

(71) Applicants: Yu-Chi Lin, Taipei (TW); Shih-Hsuan Wang, Taipei (TW)

(72) Inventors: Yu-Chi Lin, Taipei (TW); Shih-Hsuan Wang, Taipei (TW)

(73) Assignees: INVENTEC CORPORATION, Taipei (TW); INVENTEC (PUDONG) TECHNOLOGY CORPORATION, Shanghai (CN)

(21) Appl. No.: 13/599,922

(22) Filed: Aug. 30, 2012

(30) Foreign Application Priority Data
Feb. 15, 2012 (TW) 101104963

(51) Int. Cl. E05D 3/06; E05D 11/06; H05K 7/16

(52) U.S. Cl. 361/679.01; 16/371

(57) ABSTRACT

An electronic device and its biaxial pivot, the biaxial pivot comprises a connecting element, a first coupling element, a second coupling element and an elastic element. The connecting element has a first shaft and a second shaft, the first shaft and the second shaft have different axes. The first coupling element is connected to the first shaft pivotally and the second coupling element is connected to the second shaft pivotally. Two ends of the elastic element are fixed at the first coupling element and the second coupling element respectively.

### CROSS-REFERENCE TO RELATED APPLICATIONS

This non-provisional application claims priority under 35 U.S.C. §119(a) on Patent Application No(s). 101104963 filed in Taiwan, R.O.C. on Feb. 15, 2012, the entire contents of which are hereby incorporated by reference.

### BACKGROUND

1. Technical Field

The disclosure relates to a pivot and an electronic device and more particularly to a biaxial pivot and an electronic device using the biaxial pivot.

2. Related Art

Many electronic products in the markets adopt foldaway design and it is also one of the trends for the development of electronic products. Taking notebook computer as an example, the notebook computer mainly comprises a display and a mainframe, which are connected by a hinge. When a notebook computer is used, the display is capable of being unfolded relative to the mainframe by the user. The display and the mainframe are capable of being folded together when the user has finished using the notebook computer so that less space is occupied by it and it is more convenient for storing and carrying around.

Generally, the display is electrically connected to the mainframe by a signal line for transmitting information and power. The signal line in the display is connected to the mainframe through a pivot in order to prevent the signal line from being exposed and the effect of the exterior appearance.

Because the space inside the pivot structure is limited, in order for the signal line to go through the pivot and connected to the mainframe, the signal line should be converted from a flat cable into a stranded wire with a smaller size. The process for converting the flat cable into the stranded wire requires more working hours and therefore the production cost is increased. Furthermore, as notebook computer is getting slimmer, the design of the pivot structure has become a critical factor affecting the overall thickness of a notebook computer. Therefore, the pivot structure has to be designed to meet the requirement of a slim notebook computer which will increase the cost of the pivot.

### SUMMARY

The present disclosure provides a biaxial pivot, comprises a connecting element, a first coupling element, a second coupling element and an elastic element. The connecting element has a first shaft and a second shaft, wherein the first shaft and the second shaft are capable of having different axes. The first coupling element is connected to the first shaft pivotally. The second coupling element is connected to the second shaft pivotally. And in the elastic element, the two ends of the elastic element are fixed at the first coupling element and the second coupling element respectively.

The present disclosure further provides an electronic device comprises a lower case, a lateral case, an upper case and at least one biaxial pivot. The biaxial pivot comprises a connecting element, a first coupling element, a second coupling element and an elastic element. The connecting element has a first shaft and a second shaft, wherein the first shaft and the second shaft have different axes. The first coupling element is connected to the first shaft pivotally. The second coupling element is connected to the second shaft pivotally. And in the elastic element, the two ends of the elastic element are fixed at the first coupling element and the second coupling element respectively.

### BRIEF DESCRIPTION OF THE DRAWINGS

The present disclosure will become more fully understood from the detailed description given herein below for illustration only, and thus are not limitative of the present disclosure, and wherein:

FIG. 1A is a perspective view of a biaxial pivot according to an embodiment of the disclosure;

FIG. 1B is a perspective exploded view of the biaxial pivot according to an embodiment of the disclosure;

FIG. 1C is a side view of the biaxial pivot according to an embodiment of the disclosure;

FIG. 2 is a perspective view of an electronic device according to an embodiment of the disclosure; and

FIGS. 3A to 3E are illustrations of the folding and unfolding of cases of the electronic device according to an embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

Some embodiments relates to electronic devices and their biaxial pivot, by which the problem of increased manufacturing cost because a signal line has to be converted from a flat flexible cable into a stranded wire in order to be able to go through a pivot and the problem of increased cost because the pivot has to be designed to meet the requirement of a slim notebook computer can be solved

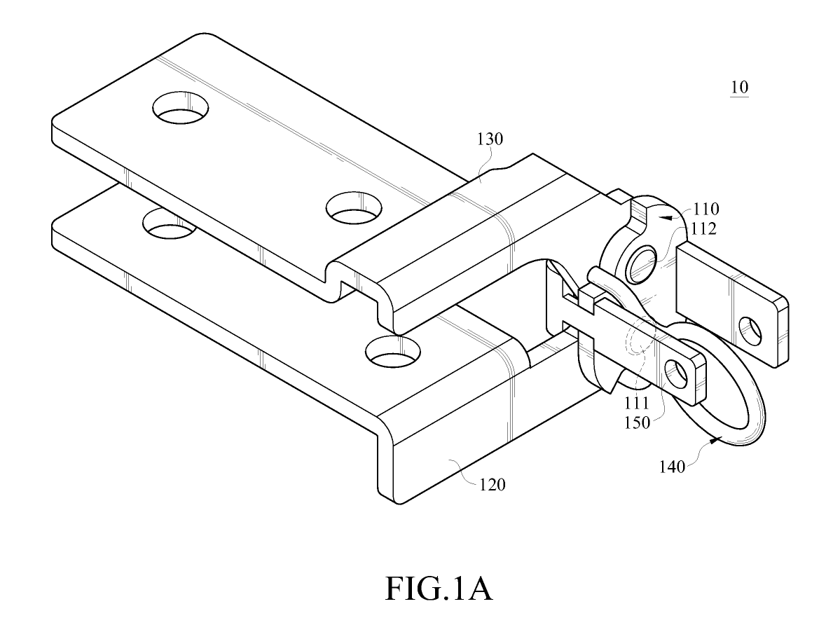

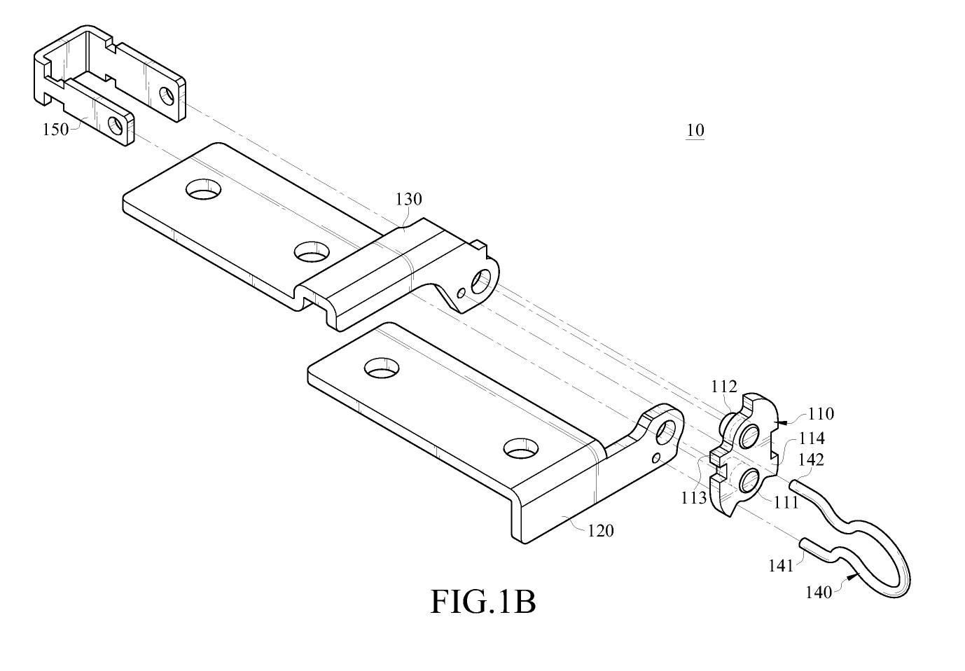

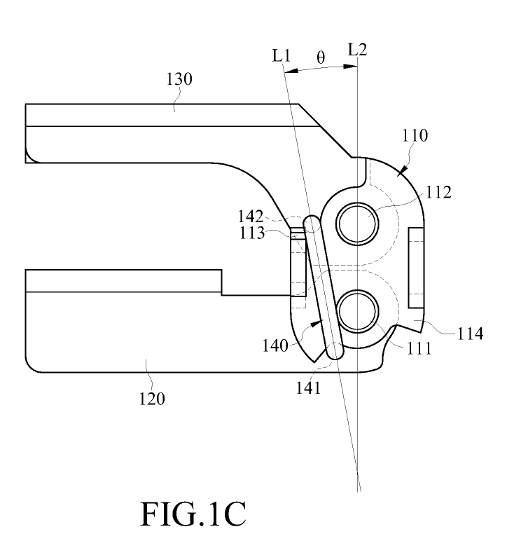

Referring to FIGS. 1A to 1C, FIG. 1A is a perspective view of a biaxial pivot according to an embodiment of the disclosure; FIG. 1B is a perspective exploded view of the biaxial pivot according to an embodiment of the disclosure; and FIG. 1C is a side view of the biaxial pivot according to an embodiment of the disclosure.

A biaxial pivot 10 of this embodiment comprises a connecting element 110, a first coupling element 120, a second coupling element 130 and an elastic element 140. The connecting element 110 has a first shaft 111 and a second shaft 112, the first shaft 111 and the second shaft 112 have different axes. The first coupling element 120 is pivotally connected to the first shaft 111, and the second coupling element 130 is pivotally connected to the second shaft 112. The elastic element 140 is a C-shaped torsional spring and has a first end 141 and a second end 142 opposite to each other. The first end 141 and the second end 142 of the elastic element 140 are fixed at the first coupling element 120 and the second coupling element 130 respectively.

Furthermore, according to this embodiment or other embodiments, the first end 141 and the second end 142 of the elastic element 140 is pass through the first coupling element 120 and the second coupling element 130 respectively, so that the first end 141 and the second end 142 are fixed at the first coupling element 120 and the second coupling element 130 respectively. Additionally, a limiting element 113 and a limiting element 114 protrude from the connecting element 110. The limiting element 113 and the limiting element 114 are disposed at two opposite sides of the connecting element 110 respectively. The limiting element 113 and the limiting element 114 are disposed corresponding to the second end 142 and the first end 141 of the elastic element 140 respectively, in order to limit the pivoting position of the first coupling element 120 or the second coupling element 130 relative to the connecting element 110 in pivoting motion. Furthermore, in this embodiment or other embodiments, the biaxial pivot 10 further comprise a fixing element 150 fixed on the connecting element 110.

Referring to FIG. 1C, in this embodiment or other embodiments, an acute angle θ is formed between a connection line L1 from the first end 141 to the second end 142 of the elastic element 140 and a connection line L2 from the axis of the first shaft 111 to the axis of the second shaft 112. Thereby, the elasticity generated by the elastic element 140 is capable of exerting different torque forces on the first shaft 111 and the second shaft 112. The cause for the different torque forces and the application of this characteristic will be explained in the following embodiments.

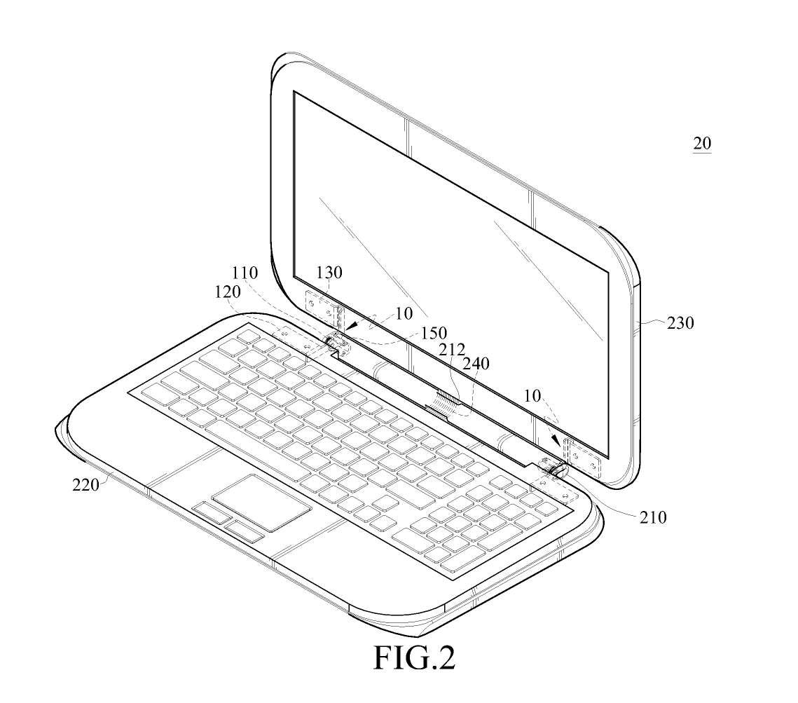

The practical application of the biaxial pivot 10 in this embodiment will be explained hereinafter. Please refer to FIG. 2, which is a perspective view of an electronic device according to an embodiment of the disclosure.

A notebook computer is used as example for an electronic device 20 of this embodiment, but the disclosure is not limited by the example. The electronic device 20 comprises a lower case 220, a lateral case 210, an upper case 230 and at least one set of the biaxial pivot 10. In this embodiment, a display case of the notebook computer is used as the upper case 230 and a mainframe case of the notebook computer is used as the lower case 220, but the disclosure is not limited by the embodiment.

In the embodiment shown in FIG. 2, the electronic device 20 with two sets of the biaxial pivots 10 is used as an example, but the quantity of the biaxial pivot 10 should not be construed as a limitation to the disclosure. The connecting element 110 of the biaxial pivot 10 is fixed to the lateral case 210 through the fixing element 150. The fixing element 150 can be coupled to the lateral case 210 by screws, but the disclosure is not limited by this embodiment. The first coupling element 120 of the biaxial pivot 10 is fixed to the lower case 220 and the second coupling element 130 of the biaxial pivot 10 is fixed to the upper case 230. The coupling of the first coupling element 120 and the lower case 220 as well as the coupling of the second coupling element 130 and the upper case 230 are capable of being implemented by screws, but the disclosure is not limited by this embodiment.

Furthermore, in this embodiment or other embodiments, the lateral case 210 further comprise a long groove 212, and the electronic device 20 further comprises a signal line 240. The signal line 240 is, for example, a flat cable transmission line. The signal line 240 passes through the groove 212 and electrically connects the lower case 220 with the upper case 230 for transmitting information and electric energy between the two cases. Therefore, the problem of the appearance affected by the exposed signal line 240 can be prevent by the signal line 240 passing through the groove 212. Furthermore, because a larger space is provided by the groove 212 of the lateral case 210, the signal line 240 is, for example, a flat flexible cable for connecting to the lower case 220 with the upper case 230 directly. In this configuration, it is unnecessary to convert the signal line 240 into a stranded wire.

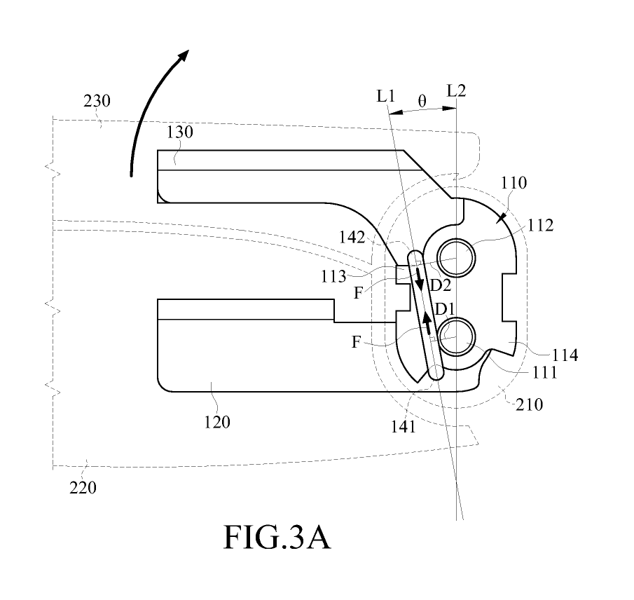

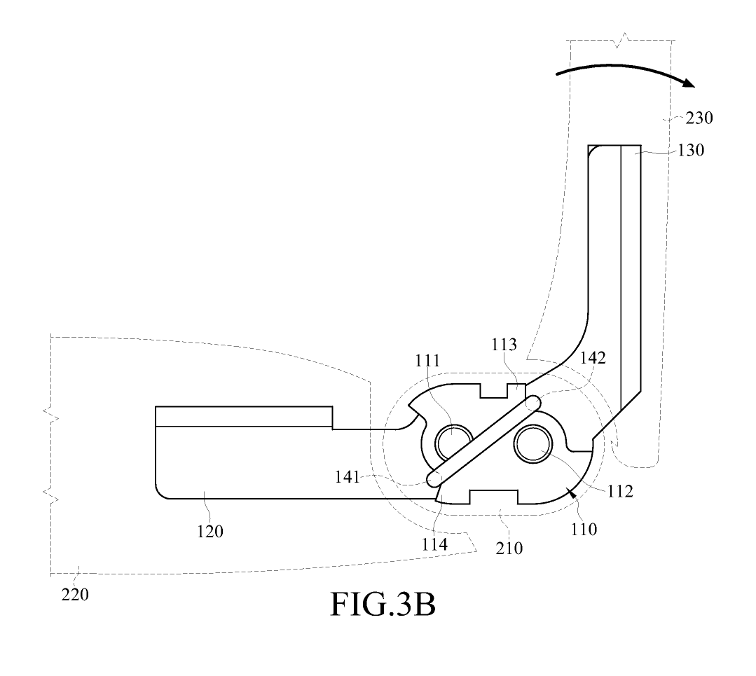

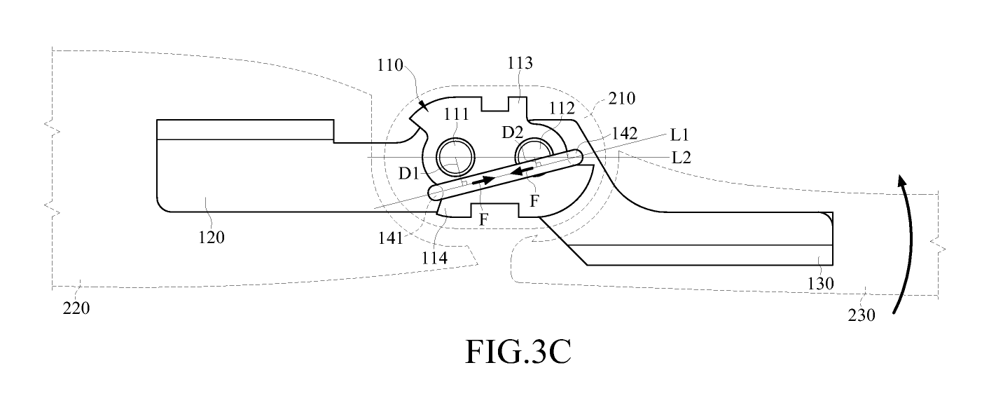

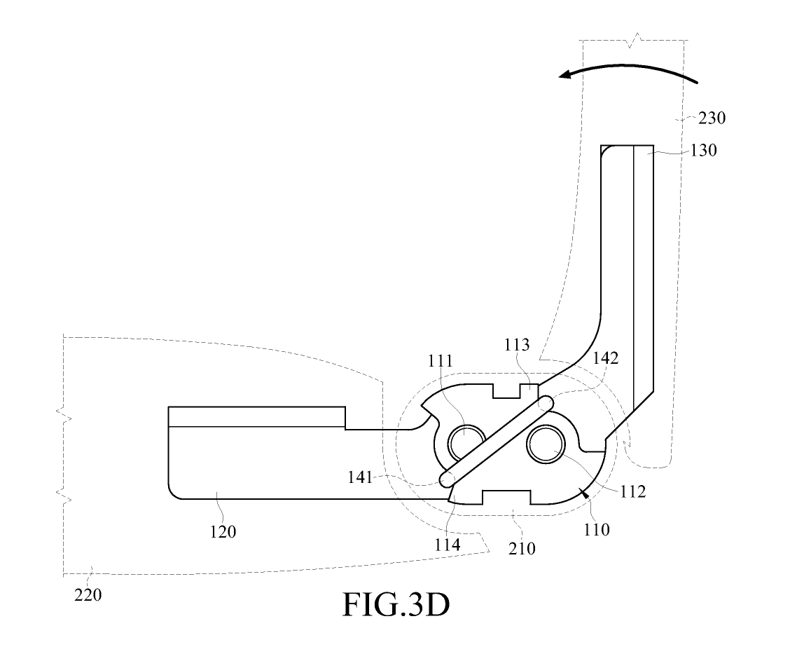

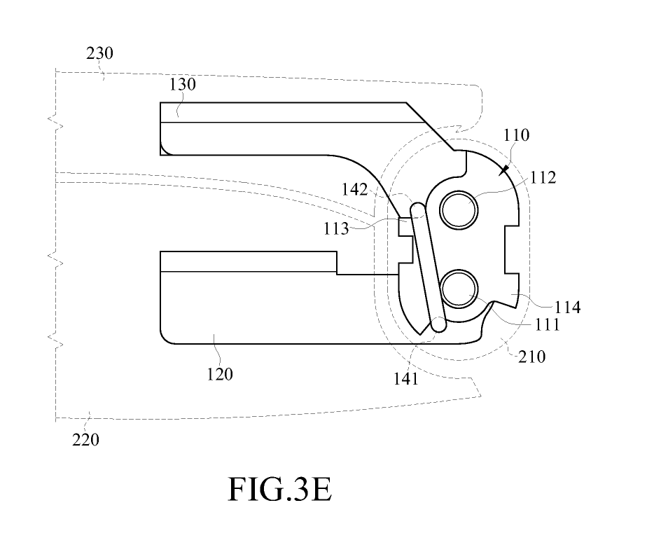

Please refer to FIGS. 3A to 3E, which are illustrations of the folding and unfolding of the cases of the electronic device according to an embodiment in the present disclosure.

When the electronic device 20 is in a folded state, the upper case 230 is folded onto the lower case 220, as shown in FIG. 3A. Referring the mechanical analysis in FIG. 3A, a tensile force F generated by the elastic element 140 is exerted on the first coupling element 120 and the second coupling element 130. The connection line L1 and the connection line L2 forms an acute angle θ rather than being paralleled to each other and the intersecting point of the connection line L1 and the connection line L2 is nearer to the first shaft 111 and is further away from the second shaft 112. Accordingly, a distance D1 of the arm of force of the tensile force F relative to the first shaft 111 is shorter than a distance D2 of the arm of force of the tensile force F relative to the second shaft 112. Thereby, the torque exerted on the second shaft 112 generated by the elastic element 140 is greater than the torque exerted on the first shaft 111 generated by the elastic element 140.

When the upper case 230 is unfolded relative to the lower case 220 by a force exerted by the user, because the torque exerted on the first shaft 111 generated by the elastic element 140 is smaller and is easier to be overcame by the force exerted by the user, the first shaft 111 will be rotated at first. More specifically, the connecting element 110 is pivoted relative to the first coupling element 120, by this way, the lateral case 210 is disposed horizontally with respect to the lower case 220 and the upper case 230 is capable of being unfolded and disposed vertically with respect to the lower case 220, referring to FIG. 3B.

When the force is exerted on the upper case 230 continuously, the limiting element 114 is pressed against the first end 141 of the elastic element 140, so that the connecting element 110 can not be pivoted relative to the first coupling element 120, while the second shaft 112 is forced to be rotated. More specifically, the second coupling element 130 is capable of being pivoted relative to the connecting element 110, so that the upper case 230 is capable of being unfolded and is capable of being at the same horizontal level as the lower case 220 as shown in FIG. 3C. At this point, referring to the mechanical analysis shown in FIG. 3C, the tensile force F generated by the elastic element 140 is still exerted on the first coupling element 120 and the second coupling element 130. The connection line L1 and the connection line L2 are capable of forming an acute angle θ rather than being paralleled to each other and the intersecting point of the connection line L1 and the connection line L2 is nearer to the second shaft 112 and is further away from the first shaft 111. Accordingly, the distance D1 of the arm of force of the tensile force F relative to the first shaft 111 is greater than the distance D2 of the arm of force of the tensile force F relative to the second shaft 112. Thereby, the torque exerted on the second shaft 112 generated by the elastic element 140 is weaker than the torque exerted on the first shaft 111 generated by the elastic element 140.

When the upper case 230 is folded onto the lower case 220 by the force exerted, because the torque exerted on the second shaft 112 generated by the elastic element 140 is weaker and is easier to be overcame by the force exerted by the user, the second shaft 112 will be rotated at first. More specifically, the second coupling element 130 is capable of being pivoted relative to the connecting element 110, which causes the upper case 230 to be folded and to be normal to the lower case 220, as shown in FIG. 3D.

When the force is exerted on the upper case 230 continuously, the limiting element 113 is pressed against the second end 142 of the elastic element 140, so that the second coupling element 130 is not capable of being pivoted relative to the connecting element 110 and the first shaft 111 is capable of being forced to rotate. More specifically, the connecting element 110 is pivoted relative to the first coupling element 120, so that the upper case 230 is capable of being folded onto on the lower case 220 as shown in FIG. 3E. Therefore, in this embodiment, the acute angle θ is formed between the connection line L1 from the first end 141 to the second end 142 of the elastic element 140 and the connection line L2 from the axis of the first shaft 111 to the axis of the second shaft 112. By this way, the elasticity generated by the elastic element 140 is capable of being exerted different torques on the first shaft 111 and the second shaft 112. Thereby, when the upper case 230 is unfolded relative to the lower case 220, the first shaft 111 and the second shaft 112 are rotated in sequence which makes it convenient for unfolding the upper case 230. Furthermore, in the above embodiment, the first shaft 111 and the second shaft 112 will rotate sequentially by taking advantage of the acute angle θ formed between the connection line L1 and the connection line L2, but this characteristic should not be construed as a limitation to the disclosure. For example, in other embodiments, by adjusting the pivoting friction coefficients of the first shaft 111 and the second shaft 112, the rotation sequence is capable being determined for the first shaft 111 and the second shaft 112.

According to the electronic device and its biaxial pivot in the present disclosure, because the structural design of the biaxial pivot is simpler than that of the conventional pivot, the cost of the biaxial pivot will be reduced. Furthermore, because the electronic device using the biaxial pivot of this embodiment provides the long groove of the lateral case in which the flat flexible cable signal line passes through, the flat flexible cable signal line is capable of being connected between the lower case and the upper case directly, and is unnecessary to convert the twisted cable signal line into a stranded wire. Additionally, the acute angle is formed between the connection line from the first end to the second end of the elastic element and the connection line from the axis of the first shaft to the axis of the second shaft. Therefore, the first shaft and the second shaft are capable of being rotated in sequence. By this configuration, a rotation sequence is capable being provided for the first shaft and the second shaft.

Note that the specifications relating to the above embodiments should be construed as exemplary rather than as limitative of the present invention, with many variations and modifications being readily attainable by a person of average skill in the art without departing from the spirit or scope thereof as defined by the appended claims and their legal equivalents.

What is claimed is:

1. A biaxial pivot, comprising:
a connecting element having a first shaft and a second shaft, the first shaft and the second shaft having different axes;
a first coupling element connected to the first shaft pivotally;
a second coupling element connected to the second shaft pivotally; and
an elastic element, two ends of the elastic element being fixed at the first coupling element and the second coupling element respectively.

2. The biaxial pivot as claimed in claim 1, wherein an acute angle is formed between a connection line of the two ends of the elastic element and the connection line from the axis of the first shaft to the axis of the second shaft.

3. The biaxial pivot as claimed in claim 1, wherein the two ends of the elastic element penetrate through the first coupling element and the second coupling element respectively, the connecting element further comprises two limiting elements corresponded to the two ends of the elastic element respectively.

4. The biaxial pivot as claimed in claim 1, wherein the two limiting elements are disposed at two opposite sides of the connecting element respectively.

5. An electronic device, comprising:
a lower case;
a lateral case;
an upper case; and
at least one biaxial pivot, comprising:
a connecting element having a first shaft and a second shaft, the first shaft and the second shaft having different axes, and the connecting element being fixed to the lateral case;
a first coupling element connected to the first shaft pivotally and fixed to the lower case;
a second coupling element connected to the second shaft pivotally and fixed to the upper case; and
an elastic element, two ends of the elastic element being fixed at the first coupling element and the second coupling element respectively.

6. The electronic device as claimed in claim 5, wherein an acute angle is formed between a connection line of the two ends of the elastic element and the connection line from the axis of the first shaft to the axis of the second shaft.

7. The electronic device as claimed in claim 5, wherein the two ends of the elastic element penetrate through the first coupling element and the second coupling element respectively, the connecting element further comprises two limiting elements corresponded to the two ends of the elastic element respectively.

8. The electronic device as claimed in claim 5, wherein the two limiting elements are disposed at two opposite sides of the connecting element respectively.

9. The electronic device as claimed in claim 5, further comprising a fixing element fixed on the connecting element, the connecting element being fixed to the lateral case through the fixing element.

10. The electronic device as claimed in claim 5, wherein the lateral case further comprises a groove, and the electronic device further comprises a signal line, the signal line passes through the groove and connected the lower case with the upper case.
